(19) United States
(12) Patent Application Publication
(10) Pub. No.: US 2007/0290363 A1
(43) Pub. Date: Dec. 20, 2007

(54) SEMICONDUCTOR DEVICE HAVING INTERFACE CHIP INCLUDING PENETRATING ELECTRODE

(76) Inventor: Kye-hyun Kyung, Yongin-si (KR)

Correspondence Address: F. CHAU & ASSOCIATES, LLC, 130 WOODBURY ROAD, WOODBURY, NY, 11797, US

(21) Appl. No.: 11/736,051

(22) Filed: Apr. 17, 2007

(30) Foreign Application Priority Data
Jun. 16, 2006 (KR) 10-2006-0054373

(51) Int. Cl. H01L 23/52

(52) U.S. Cl. 257/777

(57) ABSTRACT

A semiconductor device includes a memory chip having a memory cell array including a plurality of memory blocks, wherein the memory chip includes a plurality of test pads for testing operations of the memory blocks, and an interface chip including a penetrating electrode and a plurality of interface circuit blocks, wherein at least one of the interface circuit blocks is electrically connected to at least one of the memory blocks via the penetrating electrode, and wherein the interface chip includes a plurality of bonding pads for interfacing between the interface circuit blocks and an external device.

### CROSS-REFERENCE TO RELATED PATENT APPLICATION

This application claims priority to Korean Patent Application No. 10-2006-0054373, filed on Jun. 16, 2006, the disclosure of which is herein incorporated by reference in its entirety.

### BACKGROUND OF THE INVENTION

1. Technical Field

The present disclosure relates to a semiconductor device and, more particularly, to a semiconductor device having an interface chip including a penetrating electrode.

2. Discussion of Related Art

Semiconductor memories are widely used in various electronic devices, such as personal computers and portable devices, such as mobile phones, personal digital assistants, MP3 players or the like. As the capacity of semiconductor memories has increased, the mounting areas of semiconductor memory chips have also increased, which presents an obstacle that may limit semiconductor device miniaturization. Owing to the development of submicron technology, as the size of memory cell arrays has decreased and the number of interface signals of semiconductor memory chips has increased, pad limit has become a factor that affects the semiconductor memory chip architecture and the design process.

FIGS. 1 through 3 are diagrams for illustrating the sizes of memory chips according to pad limit. Referring to FIG. 1, a memory chip 100 includes a plurality of memory cell arrays 110, 120, 130 and 140. Pads 150 are disposed along the centerline of the memory chip 100. Referring to FIG. 1, when considering only the memory cell arrays 110 through 140, the memory chip size may be determined to be A. However, when there are many pads, the memory chip size may be increased to B due to a pad limit.

Referring to FIG. 2, when considering only the pad limit, the memory chip size may be determined to be C, for example, by arranging each of the memory cell arrays 110 through 140 separately.

Referring to FIG. 3, the memory chip size C is larger than the memory chip size A. In a memory chip of size C, the performance may be degraded since the length of signal lines becomes longer as compared to those in the memory chip 100.

Methods for fabricating high-density semiconductor memory devices have been developed. For example, Japanese Patent Laid-Open Publication No. 2005-244143 discloses a memory device having a large storage capacity using a limited mounting area. Japanese Patent Laid-Open Publication No. 2005-244143 discloses a semiconductor package having a plurality of semiconductor devices stacked one on another, in which at least one semiconductor element is electrically connected to another semiconductor element by employing a penetrating electrode.

In particular, Japanese Patent Laid-Open Publication No. 2005-244143 discloses that an interface chip is stacked on eight stacked dynamic random access memories (DRAMs), wherein the interface chip interfaces the semiconductor memory device with an external unit. The interface chip controls all of the memory cells. The interface chip includes a silicon (Si) substrate and a circuit layer having an interface function, wherein the circuit layer is formed by integrated circuit technology on the surface of the Si substrate. Each DRAM includes a Si substrate and a circuit layer including a memory cell formed by integrated circuit technology on the surface of the Si substrate. Each DRAM is equipped with a penetrating electrode which penetrates the Si substrate, whereas the interface chip is not equipped with a penetrating electrode. A conductive film of the circuit layer of the interface chip contacts the penetrating electrode of the DRAM, such that the DRAM and the interface chip can communicate with each other. The interconnect wiring between the stacked DRAMs and the interface chip is short, which may reduce the temperature increase during operation of the semiconductor memory device.

However, since the interface of each DRAM with the external unit is through the interface chip, the individual DRAMs cannot be tested independently. Since the stack of DRAMs may include a bad DRAM that is electrically connected to the other DRAMs via the penetrating electrode, a defective semiconductor package may be produced and yield may be decreased.

### SUMMARY OF THE INVENTION

According to an exemplary embodiment of the present invention, a semiconductor device includes a memory chip having a memory cell array including a plurality of memory blocks, wherein the memory chip includes a plurality of test pads for testing operations of the memory blocks, and an interface chip including a penetrating electrode and a plurality of interface circuit blocks, wherein at least one of the interface circuit blocks is electrically connected to at least one of the memory blocks via the penetrating electrode, and wherein the interface chip includes a plurality of bonding pads for interfacing between the interface circuit blocks and an external device.

The size of the memory chip may be determined based on the arrangement of the memory cell array.

The size of the interface chip may be determined based on the arrangement of the bonding pads.

The memory chip and the interface chip may be fabricated separately. A first substrate of the memory chip and a second substrate of the interface chip may be composed of the same type of material. A first substrate of the memory chip and a second substrate of the interface chip may comprise different types of materials.

The semiconductor device may comprise an adhesive material layer disposed between the memory chip and interface chip, wherein the interface chip is adhered to the memory chip. The adhesive material layer may be an underfill resin.

A portion of the penetrating electrode may protrude below the second substrate of the interface chip, wherein the protruding portion of the penetrating electrode is surrounded by the adhesive material layer.

At least one of the bonding pads may be electrically connected to at least one of the test pads.

According to an exemplary embodiment of the present invention, a semiconductor device includes a memory chip having a memory cell array including a plurality of memory blocks, and an interface chip including a penetrating electrode and a plurality of interface circuit blocks electrically connected to the memory blocks via the penetrating electrode, wherein the interface chip includes an optical interface for interfacing between the interface circuit blocks and an external device.

The memory chip may include a plurality of test pads for testing operations of the memory blocks.

The interface chip may include at least one optical device electrically connected between the interface circuit blocks and the optical interface. The optical device may be an optical emitting device, an optical diode, an optical transistor, an optical switch or an infrared detector.

The optical interface may be a nanowire that can absorb a photon from an external source and emit the photon via the optical device.

### BRIEF DESCRIPTION OF THE DRAWINGS

The present invention will become readily apparent to those of ordinary skill in the art when descriptions of exemplary embodiments thereof are read with reference to the accompanying drawings.

FIGS. 1 through 3 are diagrams for illustrating sizes of memory chips according to a pad limit.

FIGS. 4A through 4C are diagrams for illustrating a semiconductor device according to an exemplary embodiment of the present invention.

FIG. 5 shows a sectional structure of portion A of the semiconductor device of FIG. 4C.

FIG. 6 is a diagram for illustrating a semiconductor device of FIG. 4C, according to an exemplary embodiment of the present invention.

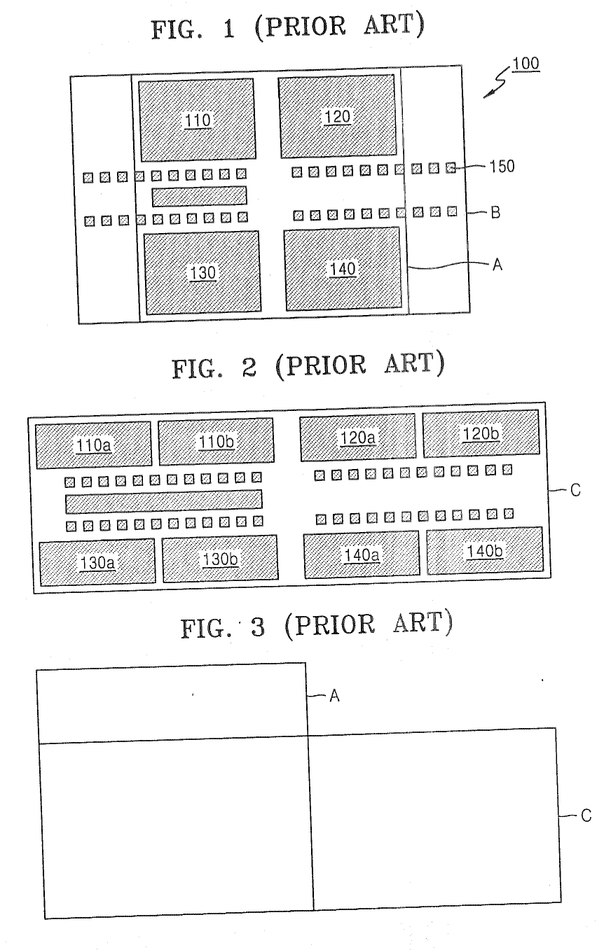

### DESCRIPTION OF EXEMPLARY EMBODIMENTS

Hereinafter, exemplary embodiments of the present invention will be described with reference to the accompanying drawings. Like reference numerals refer to similar or identical elements throughout the description of the figures. In the drawings, the sizes and thicknesses of layers and regions may be exaggerated for clarity.

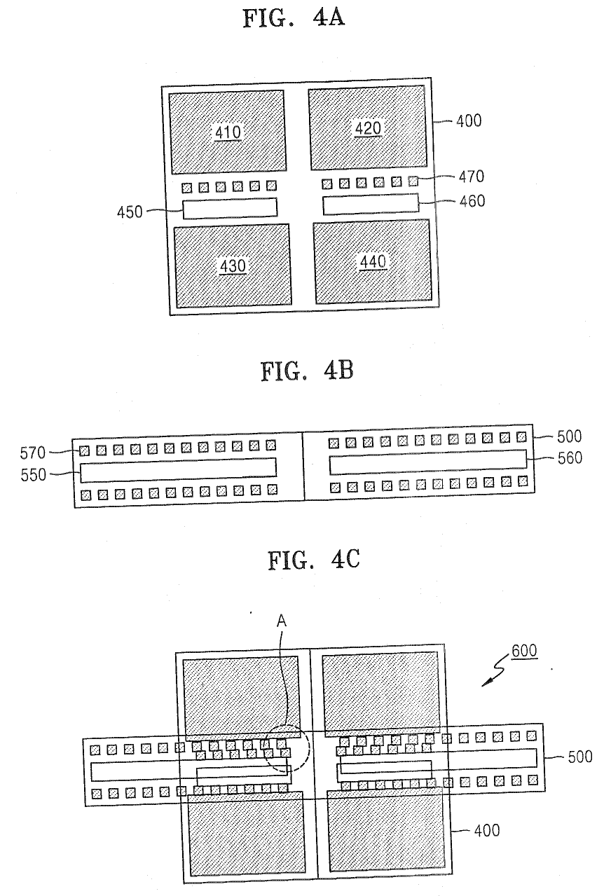

FIGS. 4A through 4C are diagrams illustrating a semiconductor device 600 according to an exemplary embodiment of the present invention. The semiconductor device 600 of FIG. 4C includes a memory chip 400 shown in FIG. 4A and an interface chip 500 shown in FIG. 4B.

The memory chip 400 includes memory cell array blocks 410, 420, 430 and 440, peripheral circuit blocks 450 and 460, and test pads 470. The size of the memory chip 400 is determined by the selected arrangement of the memory cell array blocks 410 through 440.

The interface chip 500 includes interface circuit blocks 550 and 560 for connection with the memory chip 400, and bonding pads 570. The size of the interface chip 500 is determined by the selected arrangement of the bonding pads 570. The size of the bonding pads 570 may be larger than the size of the test pads 470. The arrangement of the test pads 470 on the memory chip 400 may not be as strict as the arrangement of the bonding pads 570 on the interface chip 500. For example, the test pads 470 can be disposed in a residual area of the memory chip 400.

The interface chip 500 may be stacked on the memory chip 400. A top view of a semiconductor device 600 in which the interface chip 500 is stacked on the memory chip 400 is shown in FIG. 4C. In an exemplary embodiment of the present invention the memory chip 400 is connected to the interface chip 500 using a penetrating electrode.

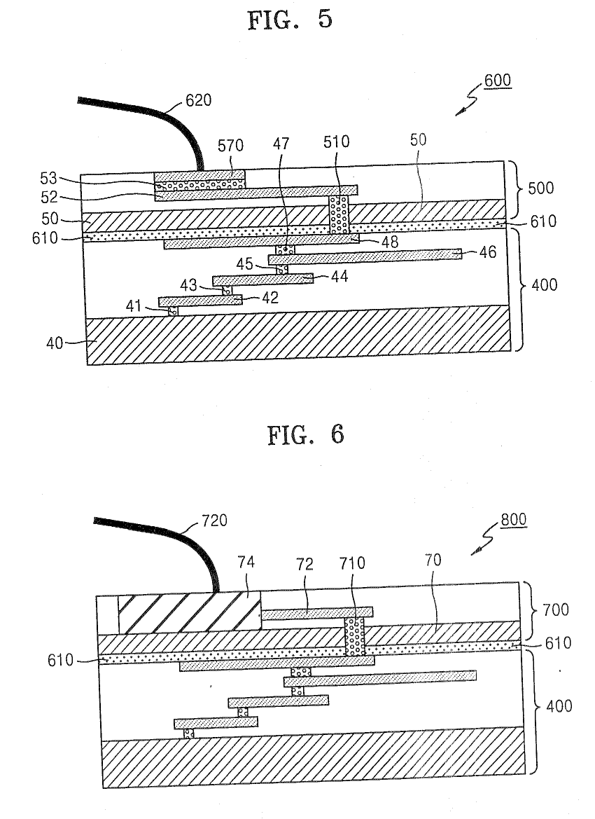

FIG. 5 shows a sectional structure of portion A of the semiconductor device of FIG. 4C. Referring to FIG. 5, the memory chip 400 and the interface chip 500 are connected using an adhesive material layer 610, such as for example, an underfill resin, which is disposed between the stacked memory chip 400 and the interface chip 500. The interface chip 500 includes a penetrating electrode 510 which penetrates a substrate 50. The penetrating electrode 510 protrudes from the substrate 50 and contacts the memory chip 400. As the adhesive material layer 610 hardens, the memory chip 400 and the interface chip 500 are bonded together.

A plurality of metal wire layers 42, 44, 46, and 48 are formed on the memory chip 400 to connect circuit patterns on the surface of a substrate 40. The metal wire layers 42, 44, 46 and 48 may be electrically connected through a contact filled with a conductive material or via holes 41, 43, 45, and 47.

A metal wire layer 52, which is connected to the penetrating electrode 510, and a bonding pad 570, which is connected to the metal wire layer 52 through a via hole 53 filled with a conductive material, are formed on the interface chip 500. A bonding wire 620 is connected to the bonding pad 570 for electrically connecting the bonding pad 570 with a ball (not shown) or a pin (not shown) of the semiconductor device 600 package.

The top metal wire layer 48 of the memory chip 400 can be used as the test pad 470 of FIG. 4A. The test pad 470 is used for testing operations of the memory chip 400 to determine whether the memory chip 400 is bad. When a signal applied to the test pad 470 is the same as a signal applied to the ball or pin of the semiconductor device 600 the bonding pad 570 of the interface chip 500 and the test pad 470 of the memory chip 400 may be electrically connected as shown in FIG. 5.

On the other hand, when a signal is applied to the test pad 470 to test operations of the memory chip 400, the test pad 470 is not electrically connected to the bonding pad 570.

The memory chip 400 may be mounted on the semiconductor device 600 after testing using the test pad 470, and the yield of the manufacturing process of the semiconductor device 600 can be increased. In an exemplary embodiment of the present invention, the memory chip 400 is designed pad free without considering a pad arrangement, and a circuit arrangement and wiring may be simplified. The production cost of the interface chip 500 is relatively low as compared to the production cost of the memory chip 400, which needs a complicated cell preparation process. The memory chip 400 and the interface chip 500 can be integrated using the same kind of substrate, such as for example, a silicon (Si) substrate, or different kinds of substrates, such as for example, a Si substrate and a gallium arsenide (GaAs) substrate.

In an exemplary embodiment of the present invention, the interface chip 500, which can be prepared separately from the tested memory chip 400, is connected through the penetrating electrode 510, and the size of the semiconductor device 600 can be reduced.

FIG. 6 is a diagram illustrating an interface chip 700 according to an exemplary embodiment of the present invention. Referring to FIG. 6, the interface chip 700 is connected to the memory chip 400 described in connection with FIG. 5 through a penetrating electrode 710 and is adhered to the memory chip 400 using an adhesive material membrane 610. The interface chip 700 includes a metal wire layer 72 connected to the penetrating electrode 710 penetrating a substrate 70, and an optical device 74 connected to the metal wire layer 72. The optical device 74 is connected to an optical interface 720.

Examples of the optical device 74 include but are not limited to an optical emitting device, an optical diode, an optical transistor, an optical switch, and an infrared detector. The optical device 74 is an energy conversion device having a photonic property. The optical interface 720 absorbs a photon from an external source and emits a photon via the optical device 74. For example, the optical interface 720 may be a nanowire.

A semiconductor device 800 including the interface chip 700, according to an exemplary embodiment of the present invention, may be capable of high speed data transmission.

Although exemplary embodiments of the present invention have been described with reference to the accompanying drawings for the purpose of illustration, it is to be understood that the inventive processes and apparatus are not be construed as limited thereby. It will be readily apparent to those of ordinary skill in the art that various modifications to the foregoing exemplary embodiments may be made without departing from the scope of the present invention as defined by the appended claims, with equivalents of the claims to be included therein.

What is claimed is:

1. A semiconductor device comprising
a memory chip having a memory cell array including a plurality of memory blocks, wherein the memory chip includes a plurality of test pads for testing operations of the memory blocks; and
an interface chip including a penetrating electrode and a plurality of interface circuit blocks, wherein at least one of the interface circuit blocks is electrically connected to at least one of the memory blocks via the penetrating electrode, and wherein the interface chip includes a plurality of bonding pads for interfacing between the interface circuit blocks and an external device.

2. The semiconductor device of claim 1, wherein a size of the memory chip is determined based on an arrangement of the memory cell array.

3. The semiconductor device of claim 1, wherein a size of the interface chip is determined based on an arrangement of the bonding pads.

4. The semiconductor device of claim 1 wherein a first substrate of the memory chip and a second substrate of the interface chip are composed of a same type of material.

5. The semiconductor device of claim 1, wherein a first substrate of the memory chip and a second substrate of the interface chip comprise different types of materials.

6. The semiconductor device of claim 1, further comprising an adhesive material layer disposed between the memory chip and the interface chip, wherein the interface chip is adhered to the memory chip.

7. The semiconductor device of claim 6, wherein the adhesive material layer is an underfill resin.

8. The semiconductor device of claim 6, wherein a portion of the penetrating electrode protrudes below the second substrate of the interface chip, and wherein the protruding portion of the penetrating electrode is surrounded by the adhesive material layer.

9. The semiconductor device of claim 1 wherein at least one of the bonding pads is electrically connected to at least one of the test pads.

10. A semiconductor device comprising
a memory chip having a memory cell array including a plurality of memory blocks; and
an interface chip including a penetrating electrode and a plurality of interface circuit blocks electrically connected to the memory blocks via the penetrating electrode,
wherein the interface chip includes an optical interface for interfacing between the second circuit blocks and an external device.

11. The semiconductor device of claim 10, wherein the memory chip further comprises a plurality of test pads for testing operations of the memory blocks.

12. The semiconductor device of claim 10, wherein the interface chip further comprises at least one optical device electrically connected between the interface circuit blocks and the optical interface.

13. The semiconductor device of claim 12, wherein the optical device is an optical emitting device, an optical diodes an optical transistor, an optical switch or an infrared detector.

14. The semiconductor device of claim 12, wherein the optical interface is a nanowire that can absorb a photon from an external source and emit the photon via the optical device.

15. The semiconductor device of claim 10, wherein a size of the memory chip is determined based on an arrangement of the memory cell array.

16. The semiconductor device of claim 10, wherein a first substrate of the memory chip and a second substrate of the interface chip are composed of the same type of material.

17. The semiconductor device of claim 10, wherein a first substrate of the memory chip and a second substrate of the interface chip comprise different types of materials.

18. The semiconductor device of claim 10, further comprising an adhesive material layer between the memory chip and the interface chip, wherein the interface chip is adhered to the memory chip.

19. The semiconductor device of claim 18, wherein the adhesive material layer is an underfill resin.

20. The semiconductor device of claim 18, wherein a portion of the penetrating electrode protrudes below the second substrate of the interface chip, and wherein the protruding portion of the penetrating electrode is surrounded by the adhesive material layer.

21. The semiconductor device of claim 10, wherein the optical interface is electrically connected to at least one of the test pads.
